(19) United States
(12) Patent Application Publication
(10) Pub. No.: US 2005/0287772 A1
(43) Pub. Date: Dec. 29, 2005

(54) Process for producing a web of a semiconductor material

(75) Inventors: Till Schlosser, Dresden (DE); Joachim Nutzel, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/145,174

(22) Filed: Jun. 6, 2005

(30) Foreign Application Priority Data
Jun. 7, 2004 (DE) 10 2004 027 691.9

(51) Int. Cl. H01L 21/20; H01L 21/36; H01L 31/20

(52) U.S. Cl. 438/483; 438/486

(57) ABSTRACT

Process for producing a web of a semiconductor material The invention relates to a process for producing two webs of a semiconductor material, in which a sacrificial web of a first material is produced on a semiconductor substrate, in which the first material is selected in such a way that the crystal structure of the semiconductor substrate is substantially transferred to the sacrificial web, in which the two webs of a semiconductor material are deposited on two opposite side walls of the sacrificial web, in which the crystal structure of the sacrificial web is substantially transferred to the crystal structure of the webs, and in which the sacrificial webs are then removed.

### CLAIM FOR PRIORITY

This application claims the benefit of priority to German Application No. 10 2004 027 691.9, filed Jun. 7, 2004, the contents of which are hereby incorporated by reference in its entirety.

### TECHNICAL FIELD OF THE INVENTION

The invention relates to a process for producing a web of a semiconductor material.

### SUMMARY OF THE INVENTION

Semiconductor geometries with web structures, the distance between which and the thickness of which is reduced further, are used in the field of semiconductor technology, and in particular in the field of DRAM memory components. Hitherto, lithographic processes with corresponding anisotropic etching processes have been used to produce parallel web structures. However, the limits of the resolution of the exposure masks used in these processes are now being reached. Moreover, anisotropic etching processes can only be used up to a certain aspect ratio. Furthermore, the low thickness of the webs means that it is also necessary to accurately control the thickness of the webs, since when a component is formed in the web, the thickness has an effect on the function of the component.

In other known processes, the feature sizes are reduced by using spacer elements in addition to the narrowing of etching openings. However, the spacer elements are also susceptible to the resolution ranges which apply to lithographic processes.

### SUMMARY OF THE INVENTION

The invention provides a process for producing a web formed from a semiconductor material with better thickness control.

According to one embodiment of the process of the invention, a sacrificial web is produced on a semiconductor substrate. Then, a web of a semiconductor material is deposited adjacent to at least one side wall of the sacrificial web. Next, the sacrificial web is removed selectively, so that the web remains in place. It is preferable for both side walls of the sacrificial web to be covered with in each case one web of the semiconductor material, with the crystal structure of the sacrificial web being transferred to the webs during the process of depositing the webs. The thickness of the webs can be accurately controlled on account of the process selected.

It is preferable for the semiconductor substrate used to be a silicon substrate. The semiconductor material used is preferably silicon, from which the webs adjoining the sacrificial web are deposited.

In a preferred embodiment, the sacrificial web is produced in the form of an epitaxially deposited and then patterned silicon-germanium layer. Silicon-germanium has the advantage that the crystal structure of a silicon substrate is transferred to the silicon-germanium layer. During a subsequent selective, epitaxial deposition of silicon on the side walls of the silicon-germanium sacrificial web, the crystal structure of the silicon substrate is also transferred to the epitaxially deposited silicon. As a result, the silicon webs have the same crystal structure as the silicon substrate. This is advantageous in particular with a view to forming channel regions for switching transistors.

It is preferable for silicon nitride to be used as hard mask for defining the width of the sacrificial web during the patterning of the sacrificial layer. In a further preferred embodiment, the thickness of the sacrificial web is additionally reduced by an etching process after the patterning of the sacrificial web. This further reduces the spacing between the webs arranged parallel.

In a further preferred embodiment, the sacrificial web is covered with a cladding layer of a semiconductor material. Then, the cladding layer is removed vertically down to as far as the sacrificial web. Next, the sacrificial web is removed selectively, so that two webs of the semiconductor material are produced.

It is preferable to use an anisotropic etching process in order to remove the cladding layer as far as the top side of the sacrificial web.

In a further preferred embodiment, the webs of silicon are applied adjacent to the side walls of the sacrificial web by a selective epitaxy process. Moreover, good process results are achieved by the cladding layer being removed anisotropically down to the top side of the sacrificial web by means of a reactive etching process.

Tests have shown that an advantageous crystal structure in the silicon webs is achieved if the sacrificial web consists of silicon-germanium and contains at most 30 mole percent of germanium. Moreover, the silicon webs have good properties for the formation of channel regions if temperatures of 1000° C. or preferably 900° C. are not exceeded during the process of depositing the silicon webs using the selective epitaxy process.

In a further preferred embodiment, the webs are produced from gallium arsenide, and the sacrificial web is produced from aluminum-gallium arsenide.

### BRIEF DESCRIPTION OF THE DRAWINGS

The invention is explained in more detail with reference to the figures, in which:

FIG. 1 shows a cross section through a silicon substrate with a sacrificial web and a hard mask.

FIG. 2 shows a sacrificial web with covered side walls.

FIG. 3 shows a cross section through a parallel wall structure.

FIG. 4 shows a semiconductor substrate with a sacrificial-web.

FIG. 5 shows a sacrificial web with a cladding layer.

FIG. 6 shows a sacrificial web with a cladding layer that has been partially etched back.

FIG. 7 shows a semiconductor substrate with a parallel web structure.

### DETAILED DESCRIPTION OF THE INVENTION

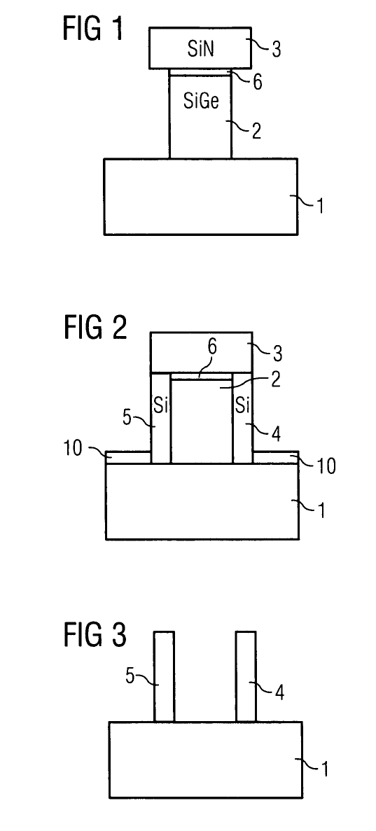

Thin webs with a high aspect ratio, and in particular with small, accurately controlled thicknesses, represent a base structure for a wide range of new transistor geometries, such as for example FIN-FETs, double-gate transistors, stacked gate transistors, etc. FIG. 1 shows a semiconductor substrate 1 which is in the form, for example, of an SOI substrate. Therefore, a single-crystal silicon crystal structure has been formed on the top side. In a first process step, a silicon-germanium layer is produced on the surface of the silicon. The silicon-germanium layer is deposited, for example, by a CVD epitaxy process. As an alternative to the epitaxy process, it is also possible for germanium ions to be implanted into the surface of the silicon crystal of the semiconductor substrate 1 and for a silicon-germanium layer to be produced by a subsequent diffusion and annealing step. The level of germanium in the silicon-germanium layer is preferably in the range of lower than 30 mole percent.

In a preferred embodiment, the sacrificial web 2 shown in FIG. 1 is covered with a pad oxide layer 6, to which the hard mask 3 has been applied. The pad oxide layer 6 is likewise removed again at the end of the process.

Then, the silicon-germanium layer is covered with a hard mask 3. It is preferable for silicon nitride to be used as material for the hard mask 3. The hard mask 3 is then patterned in the desired way using lithographic processes. In the process, it is preferable to produce parallel and rectilinear strips of hard masks 3, which have a defined width and are at a defined distance from one another. Then, the hard mask 3 is used as an etching mask in order to pattern the silicon-germanium layer 2, preferably by an anisotropic etching process. This produces a large number of silicon-germanium sacrificial webs 2 arranged parallel, which have a defined width and are at a defined distance from one another.

Depending on the embodiment selected, it is additionally possible to reduce the width of the sacrificial web 2 by the sacrificial web additionally having material removed at the side walls by an isotropic etching process. As a result, the sacrificial web 2 is also partially removed below the hard mask 3, as illustrated in FIG. 1. Suitable dry-etching processes and wet-etching processes can be used to remove the silicon-germanium layer. Etching away the sides of the silicon-germanium layer additionally produces a width of the sacrificial web which can be lower than the resolution limit for lithographic patterning processes used to produce the width of the hard mask 3 above the sacrificial web 2.

Then, the side faces of the sacrificial web 2 are covered with a semiconductor material, and in this way two parallel webs 4, 5 are produced. The semiconductor material used is preferably silicon, which is deposited on the side faces of the sacrificial web 2 by a selective epitaxial deposition process. In this process, the first and second webs 4, 5 also grow on the surface of the silicon 1 adjacent to the sacrificial web 2. To limit the growth area over which the deposited silicon can grow on the surface of the silicon crystal, a covering mask 10 is applied to the surface of the silicon using lithographic processes. The covering mask 10 preferably consists of SiO₂ and is at a defined distance from the sacrificial web 2. During deposition, the silicon grows only on the uncovered areas of the surface of the silicon 1. Then, the covering mask 10 is removed again. The selective epitaxy process has the advantage that an accuracy of 2-4% for the setting of the thicknesses of the first and second webs 4, 5 can be achieved over the course of time. This process state is illustrated in FIG. 2.

Then, in a further process step, the hard mask 3 is removed using a selective etching process, and after that the sacrificial web 2 is removed by a further selective etching process. Consequently, what remains is two first and second webs 4, 5 arranged parallel to one another and with a defined distance between them and, moreover, with a small and accurately set thickness. This process state is illustrated in FIG. 3.

The parallel webs 4, 5 are eminently suitable for forming FIN field-effect transistors. For this purpose, corresponding gate oxide layers are applied to the first and second webs 4, 5, and then gate layers are deposited thereon. Next, the source/drain regions are introduced using lithographic processes and etching processes, and corresponding doping regions for the source/drain terminal are integrated in the first and second webs 4, 5. The process for producing a FIN-FET is not explained in detail here, but rather reference is made in this respect to WO 03/081675 A1.

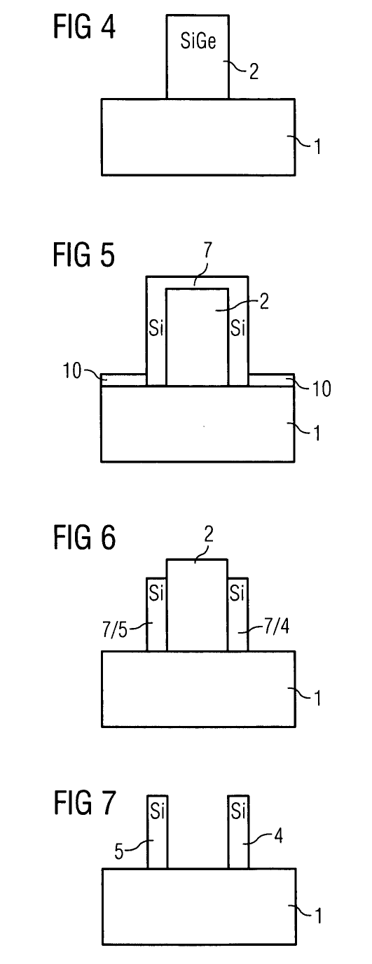

FIG. 4 shows a sacrificial web 2 which has been applied to a semiconductor substrate 1. The sacrificial web 2 preferably consists of silicon-germanium and has been produced in accordance with the processes described above in connection with FIG. 1.

The sacrificial web 2 has a defined width which has been reduced to the range of the resolution of the lithography processes as a function of the lithographic patterning processes selected. The sacrificial web 2 is then covered with a cladding layer 7, which preferably consists of silicon. In a preferred embodiment, the cladding layer 7 is applied to the sacrificial web 2 using a selective epitaxial deposition process. This process state is illustrated in FIG. 5. The cladding layer 7 covers the two side faces and the top side of the sacrificial web 2, with the cladding layer 7 also having grown in the regions of the semiconductor substrate 1 which adjoin the side faces of the sacrificial web 2. A covering mask 10 can be used to delimit the growth regions, as in the first process, with this mask being removed again after the webs 4, 5 have been deposited.

Next, in a further process, the cladding layer 7 is removed from the top side to below the top side of the sacrificial web 2 using an anisotropic material-removal process. In this context, a reactive ion etching process is used if the cladding layer 7 employed is silicon. This process state is illustrated in FIG. 6. The top side of the sacrificial web 2 has now been uncovered, so that the sacrificial web 2 can be removed using a selective etching process. If silicon-germanium is used as material for the sacrificial web 2, corresponding dry-etching and/or wet-etching processes are used to remove the silicon-germanium layer between the first and second webs 4, 5. This process state is illustrated in FIG. 7. In this way, at least one and preferably two parallel webs 4, 5 of a semiconductor material, with a defined distance between them and an accurately defined width, are produced. In this process too, the width of the first and second webs 4, 5 is substantially determined by the selective process used to deposit silicon. The selective, epitaxial silicon deposition process, which is carried out, for example, by CVD epitaxy, assists with accurate control of the thickness of the first and second webs 4, 5. Tests have shown that the desired thickness can be set with an accuracy of 2-4%.

Depending on the embodiment selected, the semiconductor material 1 may also be formed as GaAs, the sacrificial web 2 may also be formed from AlGaAs, and the deposited webs 4, 5 may also be formed from GaAs. The patterning and deposition are carried out in similar processes.

### List of Reference Numerals

1 Semiconductor substrate
2 Sacrificial web
3 Hard mask
4 First web
5 Second web
6 Pad oxide layer
7 Cladding layer
10 Covering layer

1. A process for producing at least one web of a semiconductor material, comprising:
producing a sacrificial web of a first material on a semiconductor substrate;
selecting the first material such that a crystal structure of the semiconductor substrate is substantially transferred to the sacrificial web;
depositing the web of the semiconductor material on at least one side wall of the sacrificial web;
substantially transferring the crystal structure of the sacrificial web to the crystal structure of the web; and
removing the sacrificial web.

2. The process as claimed in claim 1, wherein the semiconductor substrate used is single-crystal silicon, and the semiconductor material used to produce the two webs is silicon.

3. The process as claimed in claim 1, wherein the sacrificial web is produced from a layer of material with aid of lithography and etching processes, the etching process uses a hard mask, the sacrificial web, after vertical patterning, is laterally thinned with aid of an etching process, the web is then applied selectively to a side face of the sacrificial web, the hard mask is then removed, and the sacrificial web is removed.

4. The process as claimed in claim 3, wherein silicon nitride is used as hard mask.

5. The process as claimed in claim 1, wherein silicon-germanium is used as first material for forming the sacrificial web.

6. The process as claimed in claim 5, wherein the silicon-germanium includes between 1 and 30 mole percent of germanium.

7. The process as claimed in claim 1, wherein the sacrificial web is covered with a cladding layer of the semiconductor material, the cladding layer is removed vertically down to as far as the sacrificial web, the sacrificial web is removed, so that two webs of the semiconductor material of the cladding layer are produced.

8. The process as claimed in claim 7, wherein the cladding layer is formed from silicon, an anisotropic etching process is used to remove the cladding layer as far as a top side of the sacrificial web, and the sacrificial web is then removed using an etching process.

9. The process as claimed in claim 8, wherein the silicon is applied to the sacrificial web by selective epitaxy.

10. The process as claimed in claim 7, wherein the cladding layer is removed anisotropically as far as a top side of the sacrificial web by means of a reactive etching process.

11. The process as claimed in claim 1, wherein the semiconductor substrate used is GaAs, the sacrificial web is formed from AlGaAS, and the webs are formed from GaAs.

12. A process for producing at least one web of a semiconductor material, comprising:
producing a sacrificial web of a first material on a semiconductor substrate;
selecting the first material such that the crystal structure of the semiconductor substrate is substantially transferred to the sacrificial web;
depositing a semiconductor material on at least one side wall of the sacrificial web;
substantially transferring the crystal structure of the sacrificial web to the crystal structure of the web; and
removing the sacrificial web, wherein the sacrificial web is produced from a layer of material with aid of lithography and etching processes, the etching process uses a hard mask, the sacrificial web, after vertical patterning, is laterally thinned with aid of an etching process, the web is applied selectively to a side face of the sacrificial web, the hard mask is removed, and the sacrificial web is removed.
